(19) United States
(12) Patent Application Publication
(10) Pub. No.: US 2014/0008745 A1
(43) Pub. Date: Jan. 9, 2014

(54) SOLID-STATE IMAGING DEVICE AND ELECTRONIC APPARATUS

(71) Applicant: Sony Corporation, Tokyo (JP)

(72) Inventor: Shunsuke Maruyama, Kanagawa (JP)

(21) Appl. No.: 13/926,355

(22) Filed: Jun. 25, 2013

(30) Foreign Application Priority Data
Jul. 3, 2012 (JP) 2012149099

(51) Int. Cl. H01L 31/0328

(52) U.S. Cl. CPC H01L 31/0328
USPC 257/431

(57) ABSTRACT

There is provided a solid-state imaging device including a pixel substrate in which a wire layer and a semiconductor element are formed using a wire material which can endure temperature at a time of forming a photoelectric conversion layer, and a logic substrate in which a semiconductor element is formed. The wire layer side of the pixel substrate is joined to a rear side of the logic substrate, and, after the photoelectric conversion layer is formed on a rear side of the pixel substrate, a wire layer is formed in the logic substrate such that the wire layers are disposed on a front side of the pixel substrate and the photoelectric conversion layer is disposed on the rear side of the pixel substrate.

### BACKGROUND

The present technology relates to a solid-state imaging device and an electronic apparatus, and particularly to a solid-state imaging device and an electronic apparatus capable of preventing deterioration in characteristics of a photoelectric conversion layer and securing reliability of a wire layer.

A solid-state imaging device is required to have a reduced pixel size and high sensitivity. In addition, there is also a request for reduction in occurrence of a dark current so as to achieve high image quality. In order to satisfy these requests, it has been proposed by the same assignee as the present application that a solid-state imaging device capable of reducing a dark current and achieving high sensitivity by using, for example, a chalcopyrite-based compound semiconductor which is lattice-matched on a silicon substrate as a photoelectric conversion layer (for example, refer to Japanese Unexamined Patent Application Publication No. 2011-146635 (FIG. 30)).

### SUMMARY

FIG. 30 of Japanese Unexamined Patent Application Publication No. 2011-146635 shows a solid-state imaging device in which a lattice-matched chalcopyrite-based compound semiconductor is formed as a photoelectric conversion layer on a rear side of the silicon substrate, and, a semiconductor element such as a transistor, and a wire layer using Al, Cu, or the like are formed on a front side of the silicon substrate.

Here, heating at temperature of 400° C. or more is necessary to form a photoelectric conversion layer through epitaxial growth or film formation, heating at temperature of 800° C. or more is necessary to form a semiconductor element such as a transistor, for example, a gate oxide film, and heating at temperature of 1000° C. or more is necessary for impurity activation annealing. For this reason, if the semiconductor element is formed after forming the photoelectric conversion layer, other compounds are formed or a layer is separated into different layers due to the heat of 800° C. or more at the time of forming the semiconductor element and thereby characteristics of the photoelectric conversion layer deteriorate. As a result, image quality of an image sensor deteriorates. On the other hand, if the photoelectric conversion layer is formed after forming the wire layer, reliability of the wire layer fails to be secured due to the heat of 400° C. or more at a time of forming the photoelectric conversion layer.

Embodiments of the present technology have been made in consideration of these circumstances, and enables deterioration in characteristics of a photoelectric conversion layer to be prevented and reliability of a wire layer to be secured.

According to a first embodiment of the present technology, there is provided a solid-state imaging device including a pixel substrate in which a wire layer and a semiconductor element are formed using a wire material which can endure temperature at a time of forming a photoelectric conversion layer, and a logic substrate in which a semiconductor element is formed. The wire layer side of the pixel substrate is joined to a rear side of the logic substrate, and, after the photoelectric conversion layer is formed on a rear side of the pixel substrate, a wire layer is formed in the logic substrate such that the wire layers are disposed on a front side of the pixel substrate and the photoelectric conversion layer is disposed on the rear side of the pixel substrate.

According to the first embodiment of the present technology, the wire layer side of the pixel substrate in which the wire layer and the semiconductor element are formed using the wire material which can endure temperature at the time of forming the photoelectric conversion layer is joined to the rear side of the logic substrate in which the semiconductor element is formed, and, after the photoelectric conversion layer is formed on the rear side of the pixel substrate, the wire layer is formed in the logic substrate such that the wire layers are disposed on the front side of the pixel substrate and the photoelectric conversion layer is disposed on the rear side of the pixel substrate.

According to a second embodiment of the present technology, there is provided a solid-state imaging device including a pixel substrate in which a wire layer and a semiconductor element are formed on a front side of a semiconductor substrate by using a wire material which can endure temperature at a time of forming a photoelectric conversion layer, a support substrate is then joined to the front side of the semiconductor substrate, and the photoelectric conversion layer is formed on a rear side of the semiconductor substrate, and a logic substrate manufactured separately from the pixel substrate. The pixel substrate is joined to the logic substrate such that the pixel substrate is electrically connected to the logic substrate, and the wire layer is disposed on a front side of the pixel substrate and the photoelectric conversion layer is disposed on a rear side of the pixel substrate.

According to the second embodiment of the present technology, the pixel substrate, in which the wire layer and the semiconductor element are formed on the front side of the semiconductor substrate by using the wire material which can endure temperature at the time of forming the photoelectric conversion layer, the support substrate is then joined to the front side of the semiconductor substrate, and the photoelectric conversion layer is formed on the rear side of the semiconductor substrate, is joined to the logic substrate manufactured separately from the pixel substrate such that the pixel substrate is electrically connected to the logic substrate, and the wire layer is disposed on the front side of the pixel substrate and the photoelectric conversion layer is disposed on the rear side of the pixel substrate.

According to a third embodiment of the present technology, there is provided a solid-state imaging device including a pixel substrate that is formed by, after a semiconductor element is formed on a front side of a semiconductor substrate, joining a support substrate to the front side of the semiconductor substrate, and, after a photoelectric conversion layer is formed on a rear side of the semiconductor substrate, forming a wire layer. The wire layer is disposed on a front side of the pixel substrate and the photoelectric conversion layer is disposed on a rear side of the pixel substrate.

According to the third embodiment of the present technology, the pixel substrate is formed by, after the semiconductor element is formed on the front side of the semiconductor substrate, joining the support substrate to the front side of the semiconductor substrate, and, after the photoelectric conversion layer is formed on the rear side of the semiconductor substrate, forming the wire layer, so that the wire layer is disposed on the front side of the pixel substrate and the photoelectric conversion layer is disposed on the rear side of the pixel substrate.

According to the first to third embodiments of the present technology, it is possible to prevent deterioration in characteristics of the photoelectric conversion layer and to secure reliability of the wire layer.

### BRIEF DESCRIPTION OF THE DRAWINGS

FIG. 1 is a schematic configuration diagram of a solid-state imaging device to which an embodiment of the present technology is applied;

FIGS. 2A to 2C are diagrams illustrating substrate configurations of the solid-state imaging device of FIG. 1;

FIG. 3 is a schematic cross-sectional view of a pixel;

FIGS. 4A to 4G are diagrams illustrating a first manufacturing method of the solid-state imaging device;

FIGS. 5A to 5F are diagrams illustrating a second manufacturing method of the solid-state imaging device;

FIGS. 6A to 6D are diagrams illustrating the second manufacturing method of the solid-state imaging device;

FIGS. 7A to 7G are diagrams illustrating a third manufacturing method of the solid-state imaging device;

FIGS. 8A to 8D are diagrams illustrating the third manufacturing method of the solid-state imaging device;

FIGS. 9A to 9E are diagrams illustrating a fourth manufacturing method of the solid-state imaging device;

FIGS. 10A to 10C are diagrams illustrating the fourth manufacturing method of the solid-state imaging device;

FIGS. 11A to 11F are diagrams illustrating a fifth manufacturing method of the solid-state imaging device;

FIGS. 12A and 12B are diagrams illustrating a sixth manufacturing method of the solid-state imaging device;

FIGS. 13A to 13D are diagrams illustrating the sixth manufacturing method of the solid-state imaging device;

FIGS. 14A and 14B are diagrams illustrating the sixth manufacturing method of the solid-state imaging device; and

FIG. 15 is a block diagram illustrating a configuration example of an imaging apparatus as an electronic apparatus to which an embodiment of the present technology is applied.

### DETAILED DESCRIPTION OF THE EMBODIMENT(S)

[Schematic Configuration Example of Solid-State Imaging Device]

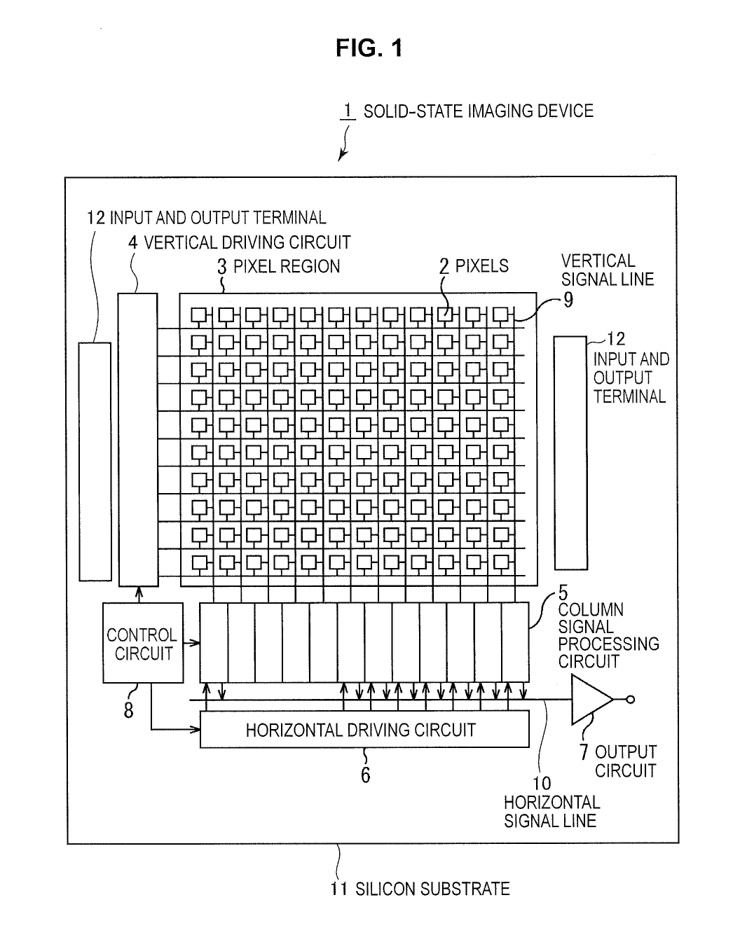

FIG. 1 shows a schematic configuration of a solid-state imaging device to which an embodiment of the present technology is applied. The solid-state imaging device 1 of FIG. 1 is a bask-side illumination type MOS solid-state imaging device.

The solid-state imaging device 1 of FIG. 1 includes a pixel region 3 in which pixels 2 including photoelectric conversion units are regularly arranged in a two-dimensional array form over a silicon substrate 11 which uses silicon (Si) as a semiconductor, and a peripheral circuit unit located around the pixel region 3. The peripheral circuit unit includes a vertical driving circuit 4, a column signal processing circuit 5, a horizontal driving circuit 6, an output circuit 7, a control circuit 8, and the like.

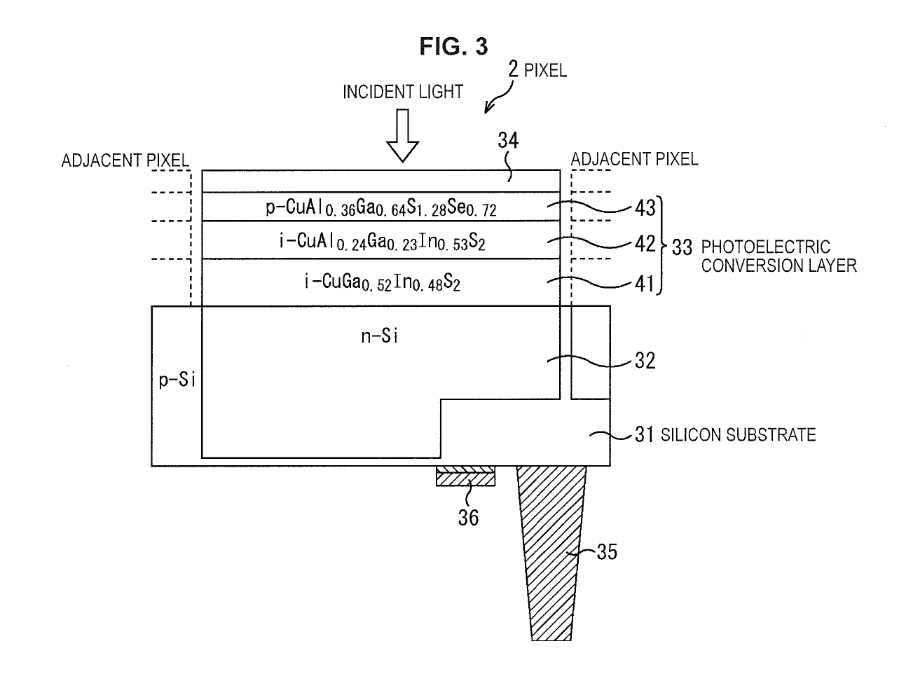

The pixel 2 includes a plurality of photoelectric conversion layers 33 (FIG. 3) which are photoelectric conversion units and a plurality of pixel transistors (so-called MOS transistors). A plurality of pixel transistors may be constituted by three transistors including, for example, a transfer transistor, a reset transistor, and an amplification transistor. The pixel 2 may be constituted by four transistors by including an additional selection transistor.

The pixel 2 may be formed as a single unit pixel. An equivalent circuit of the unit pixel is the same as that of a typical pixel and thus detailed description thereof will be omitted. In addition, the pixel 2 may be configured as a pixel sharing structure. The pixel sharing structure includes a plurality of photodiodes, a plurality of transfer transistors, a shared single floating diffusion, and a shared single other pixel transistor. In other words, in the shared pixel, the photodiodes and transfer transistors forming a plurality of unit pixels share a single other pixel transistor.

The control circuit 8 receives an input clock and data for instructing an operation mode or the like, and outputs data such as internal information of the solid-state imaging device 1. In other words, the control circuit 8 generates a clock signal which is used as a reference of operations of the vertical driving circuit 4, the column signal processing circuit 5, the horizontal driving circuit 6 and the like, or a control signal on the basis of a vertical synchronization signal, a horizontal synchronization signal, and a master clock. In addition, the control circuit 8 inputs the generated clock signal or control signal to the vertical driving circuit 4, the column signal processing circuit 5, the horizontal driving circuit 6, and the like.

The vertical driving circuit 4 includes, for example, shift registers, selects a pixel driving wire, supplies a pulse for driving pixels to the selected pixel driving wire, and drives the pixels row by row. In other words, the vertical driving circuit 4 sequentially selectively scans the respective pixels 2 of the pixel region 3 in the vertical direction row by row, and supplies a pixel signal based on signal charge which is generated according to a light receiving amount of the photoelectric conversion unit of each pixel 2 to the column signal processing circuit 5 via a vertical signal line 9.

The column signal processing circuit 5 is disposed, for example, for each column of the pixels 2, and performs a signal process such as noise removal on signals output from the pixels 2 of one row for each column. In other words, the column signal processing circuit 5 performs signal processes such as CDS (Correlated Double Sampling), signal amplification, or AD conversion in order to remove fixed pattern noise unique to the pixels 2.

The horizontal driving circuit 6 includes, for example, shift registers, and sequentially outputs horizontal scanning pulses so as to sequentially select the column signal processing circuits 5 and to cause pixel signals from the respective column signal processing circuits 5 to be outputted to a horizontal signal line 10.

The output circuit 7 performs a signal process on signals which are sequentially supplied from the respective column signal processing circuits 5 via the horizontal signal line 10, and outputs the processed signal. The output circuit 7 may perform, for example, only buffering, or may perform black level adjustment, column variation correction, various digital signal processes, and the like. An input and output terminal 12 sends and receives signals to and from external devices.

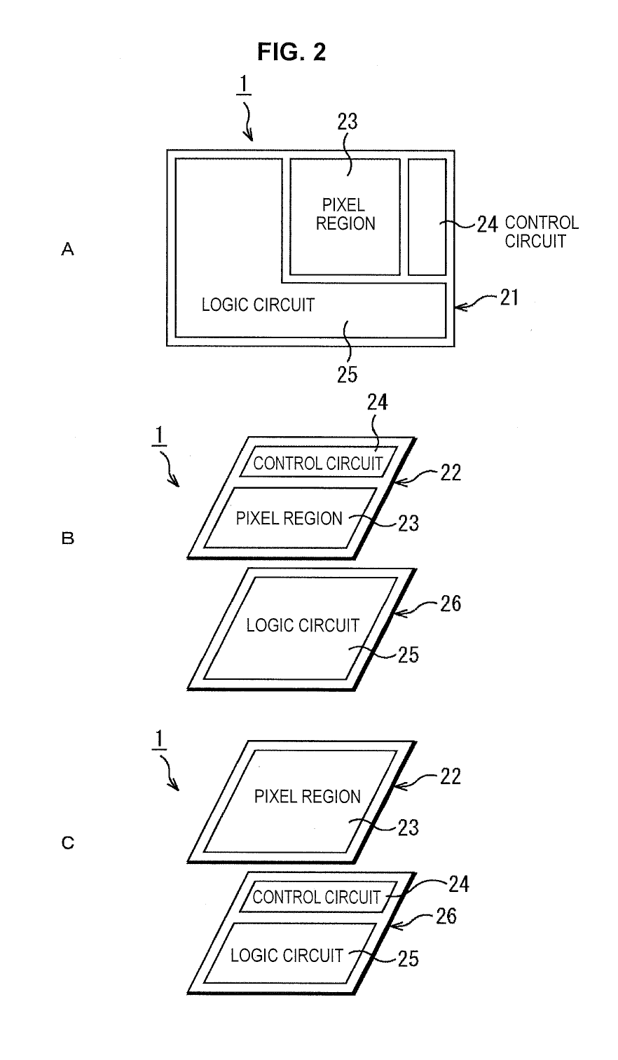

A substrate configuration of the solid-state imaging device 1 of FIG. 1 will be described with reference to FIGS. 2A to 2C.

FIG. 2A shows a first substrate configuration of the solid-state imaging device 1. The solid-state imaging device 1 of FIG. 2A includes a pixel region 23, a control circuit 24, and a logic circuit 25 for processing signals, mounted on a single semiconductor substrate 21. The semiconductor substrate 21 of FIG. 2A corresponds to the silicon substrate 11 of FIG. 1, and the pixel region 23 of FIG. 2A corresponds to the pixel region 3 of FIG. 1.

FIGS. 2B and 2C show second and third substrate configurations of the solid-state imaging device 1, respectively. The solid-state imaging devices 1 of FIGS. 2B and 2C have a structure in which the pixel region 23 and the logic circuit 25 are formed over the respective corresponding semiconductor substrates and laminated to each other.

In the solid-state imaging device 1 of FIG. 2B, the pixel region 23 and the control circuit 24 are mounted on the first semiconductor substrate 22, and the logic circuit 25 including a signal processing circuit for processing a signal is mounted on the second semiconductor substrate 26. The first semiconductor substrate 22 and the second semiconductor substrate 26 are electrically connected to each other, and both of the first semiconductor substrate 22 and the second semiconductor substrate 26 correspond to the silicon substrate 11 of FIG. 1.

In the solid-state imaging device 1 of FIG. 2C, the pixel region 23 is mounted on the first semiconductor substrate 22, and the control circuit 24 and the logic circuit 25 including a signal processing circuit are mounted on the second semiconductor substrate 26. The first semiconductor substrate 22 and the second semiconductor substrate 26 are electrically connected to each other, and both of the first semiconductor substrate 22 and the second semiconductor substrate 26 correspond to the silicon substrate 11 of FIG. 1.

As in FIGS. 2B and 2C, a manufacturing method of a solid-state imaging device, in which the first semiconductor substrate 22 with the pixel region 23 formed and the second semiconductor substrate 26 with the logic circuit 25 formed are formed separately using a semiconductor process technique, are then joined to each other, and are electrically connected to each other, is disclosed in Japanese Unexamined Patent Application Publication Nos. 2010-245506 and 2011-96851, owned by the same assignee as the present application. The substrates are formed through a separate process and are then joined to each other, which leads to contribution to high image quality, mass productivity, and low costs. In addition, hereinafter, the first semiconductor substrate 22 with the pixel region 23 formed is also referred to as a pixel substrate 22, and the second semiconductor substrate 26 with the logic circuit 25 formed is also referred to as a logic substrate 26.

[Schematic Cross-Sectional View of Pixel]

FIG. 3 is a schematic cross-sectional view of the pixel 2.

As shown in FIG. 3, a silicon substrate 31 is formed of a p-type silicon substrate. A first electrode layer 32 is formed in the silicon substrate 31 and extends to the vicinity of the rear side of the silicon substrate 31. The first electrode layer 32 is formed of, for example, an n-type silicon region formed in the silicon substrate 31.

A photoelectric conversion layer 33 made of a chalcopyrite-based compound semiconductor including a lattice-matched copper-aluminum-gallium-indium-sulfur-selenium (hereinafter, referred to as CuAlGaInSSe)-based mixed crystal is formed over the first electrode layer 32. The photoelectric conversion layer 33 includes a first photoelectric conversion film 41 made of i-CuGa_{0.52}In_{0.48}S₂, a second photoelectric conversion film 42 made of i-CuAl_{0.24}Ga_{0.23}In_{0.53}S₂, and a third photoelectric conversion film 43 made of _{p-CuAl}_{0.36}Ga_{0.64}S_{1.28}Se_{0.72} laminated on the first electrode layer 32. Therefore, the photoelectric conversion layer 33 has a p-i-n structure as a whole. CuGa_{0.52}In_{0.48}S₂ of the first photoelectric conversion film 41 is an R spectral photoelectric conversion material, CuAl_{0.24}Ga_{0.23}In_{0.53}S₂ of the second photoelectric conversion film 42 is a G spectral photoelectric conversion material, and CuAl_{0.36}Ga_{0.64}S_{1.28}Se_{0.72} of the third photoelectric conversion film 43 is a B spectral photoelectric conversion material. As above, the R spectral photoelectric conversion material, the G spectral photoelectric conversion material, and the B spectral photoelectric conversion material are laminated in this order over the silicon substrate 31, and thereby light can be separated in the depth direction.

In addition, a copper-aluminum-gallium-indium-zinc-sulfur-selenium (hereinafter, referred to as CuAlGaInZnSSe)-based mixed crystal may be used as the chalcopyrite-based compound semiconductor.

In addition, a light-transmissive second electrode layer 34 is formed over the photoelectric conversion layer 33. The second electrode layer 34 is made of a transparent electrode material such as, for example, indium tin oxide (ITO), zinc oxide, indium-zinc oxide.

In addition, a MOS transistor, a plug (connection conductor) 35 connected thereto, and the like are formed on the front side (the lower side of the silicon substrate 31 in the figure) of the silicon substrate 31. In FIG. 3, a gate electrode 36 of a single MOS transistor is shown. The plug 35 is formed using a wire material such as, for example, tungsten (W), which can secure reliability even in the heat higher than the temperature (400° C.) at a time of forming the photoelectric conversion layer. The gate electrode 36 is formed using, for example, poly-silicon.

The photoelectric conversion layer 33 of the chalcopyrite-based compound which separates light into RGB in the depth direction is formed so that it may be lattice-matched on the silicon substrate 11. The photoelectric conversion layer 33 is lattice-matched on the silicon substrate 31 by using a mixed crystal of the chalcopyrite-based material with a high light absorption coefficient and is epitaxially grown, thus crystallinity becomes favorable, and, as a result, a high sensitivity solid-state imaging device 1 with a low dark current is provided.

In the pixel structure in which the semiconductor element such as the MOS transistor is formed on the front side of the silicon substrate 31 and the photoelectric conversion layer 33 is formed on the rear side of the silicon substrate 31 as shown in FIG. 3, there are the following problems in terms of manufacturing in the related art. In other words, heating at temperature of 800° C. or more is necessary to form the semiconductor element, and heating at temperature of 400° C. or more is necessary to form the photoelectric conversion layer. If the semiconductor element is formed after forming the photoelectric conversion layer, there is a problem in that characteristics of the photoelectric conversion layer deteriorate due to the heat of 800° C. or more at the time of forming the semiconductor element. If the photoelectric conversion layer is formed after forming the semiconductor element and the wire layer, there is a problem in that reliability of the wire layer fails to be secured due to the heat higher than 400° C. at a time of forming the photoelectric conversion layer. Therefore, manufacturing methods for solving these problems will now be described.

In addition, according to the present embodiment, the photoelectric conversion layer 33 formed on the rear side of the silicon substrate 31 has a three-layer structure which separates light into RGB in the depth direction as described with reference to FIG. 3; however, the manufacturing methods described in the following are also applicable to cases where the photoelectric conversion layer 33 has a single layer structure or a two-layer structure as disclosed in, for example,

Japanese Unexamined Patent Application Publication No. 2011-199057 in the same manner.

[First Manufacturing Method of Solid-State Imaging Device]

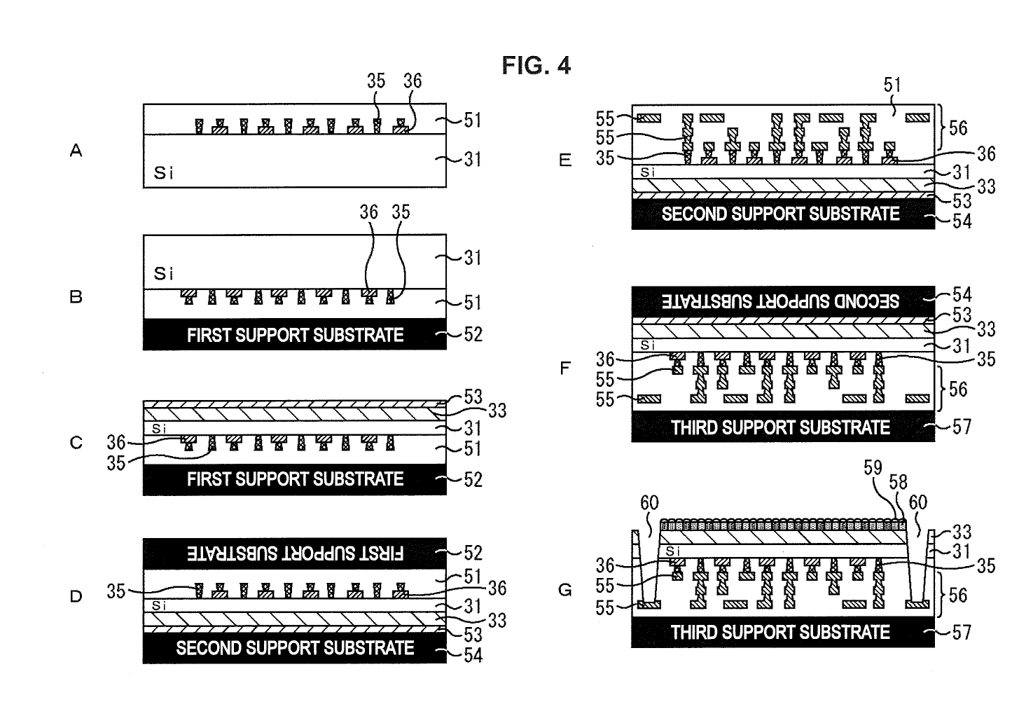

First, with reference to FIGS. 4A to 4G, a first manufacturing method of the solid-state imaging device 1 will be described. The first manufacturing method described below is a manufacturing method corresponding to the solid-state imaging device 1 with a configuration in which the pixel region 23 and the control circuit 24 are disposed in the horizontal direction (transverse direction) as shown in FIG. 2A.

In a first process, as shown in FIG. 4A, semiconductor elements such as MOS transistors and plugs 35 are formed over the silicon substrate 31. In addition, in FIGS. 4A to 4G and thereafter, only the gate electrodes 36 are shown in the same manner as in FIG. 3 among a plurality of semiconductor elements (MOS transistors) which are formed as a portion of the pixel 2. A region other than the semiconductor elements and the plugs 35 over the silicon substrate 31 is covered by an interlayer insulating layer 51. The plugs 35 are formed by forming connection holes after the interlayer insulating layer 51 is formed and then by burying connection conductors.

In addition, in the following description, the entire substrate including the silicon substrate 31 and films or a wire layer laminated thereon is also referred to as a silicon wafer.

Next, in a second process, as shown in FIG. 4B, the silicon wafer is reversed, and a first support substrate 52 is joined to the front side of the silicon substrate 31.

In a third process, as shown in FIG. 4C, the silicon substrate 31 is thinned through polishing or etching, and then a photoelectric conversion layer 33 and a protection film 53 are formed thereon. The protection film 53 may be formed of, for example, silicon oxide (SiO₂) or silicon nitride (SiN).

In forming the photoelectric conversion layer 33, heating at temperature higher than 400° C. is necessary as described above; however, the plugs 35 are formed using a wire material such as tungsten (W) which can secure reliability even in the heat higher than 400° C., and thus reliability of a wire is not reduced.

Next, in a fourth process, as shown in FIG. 4D, the silicon wafer is reversed again, and a second support substrate 54 is joined to the protection film 53 side which is the rear side of the silicon substrate 31.

In a fifth process, after the first support substrate 52 is peeled off in the state shown in FIG. 4D, a wire layer 56 including multi-layer wires 55 are formed on the front side of the silicon substrate 31 as shown in FIG. 4E. The wires 55 include, for example, the above-described pixel driving lines and vertical signal lines 9, and a wire material of the wires 55 uses, for example, Al or Cu. The region other than the multi-layer wires 55 of the wire layer 56 is the interlayer insulating layer 51.

In a sixth process, as shown in FIG. 4F, the silicon wafer is reversed again, and a third support substrate 57 is joined to the wire layer 56 side which is the front side of the silicon substrate 31.

In a seventh process, as shown in FIG. 4G, the second support substrate 54 is peeled off in the state shown in FIG. 4F, and then the protection film 53 which is formed on the uppermost surface is removed. In addition, color filters 58 and on-chip lenses (OCL) 59 are formed over the photoelectric conversion layer 33 which is exposed by removing the protection film 53, and PAD openings 60 are also formed. In addition, although the protection film 53 is removed in this example, the protection film 53 may be remained in another example.

As above, according to the first manufacturing method, the semiconductor elements are formed on the front side of the silicon substrate 31, the first support substrate 52 is joined to the front side of the silicon substrate 31, the photoelectric conversion layer 33 is formed on the rear side of the silicon substrate 31, and then the wire layer 56 is formed, thereby manufacturing the solid-state imaging device 1. As a result, there is a completion of the solid-state imaging device 1 with the structure shown in FIG. 3 in which the semiconductor elements and the wire layer 56 are disposed on the front side (the lower side of the silicon substrate 31 in the figure) of the silicon substrate 31, and the photoelectric conversion layer 33, the color filters 58, and the like are disposed on the rear side (the upper side of the silicon substrate 31 in the figure) of the silicon substrate 31.

In the first manufacturing method, heating of 800° C. or more is necessary to form the semiconductor elements in the first process (FIG. 4A), but since this first process precedes the third process (FIG. 4C) in which the photoelectric conversion layer 33 is formed, the photoelectric conversion layer 33 is not formed yet, and thus there is no concern about deterioration in characteristics of the photoelectric conversion layer 33 due to the heating at high temperature of 800° C. or more.

Further, since the photoelectric conversion layer 33 is formed in the third process (FIG. 4C) before the wire layer 56 is formed in the fifth process (FIG. 4E), the heat higher than 400° C. at the time of forming the photoelectric conversion layer 33 is not applied to the wire layer 56, and thus it is possible to maintain reliability of the wire layer 56.

Therefore, according to the first manufacturing method, it is possible to prevent deterioration in characteristics of the photoelectric conversion layer and secure reliability of the wire layer.

Although, in the above-described example, the interlayer insulating layer 51 is formed and then the plugs 35 are also formed in the first process, the plugs 35 may not be formed in the first process, and the plugs 35 may be formed after the first support substrate 52 is peeled off in the fifth process (FIG. 4E). In other words, as the timing when the plugs 35 are formed, either the first process or the fifth process may be appropriately selected in consideration of a temperature condition or the like when the plugs 35 are formed.

[Second Manufacturing Method of Solid-State Imaging Device]

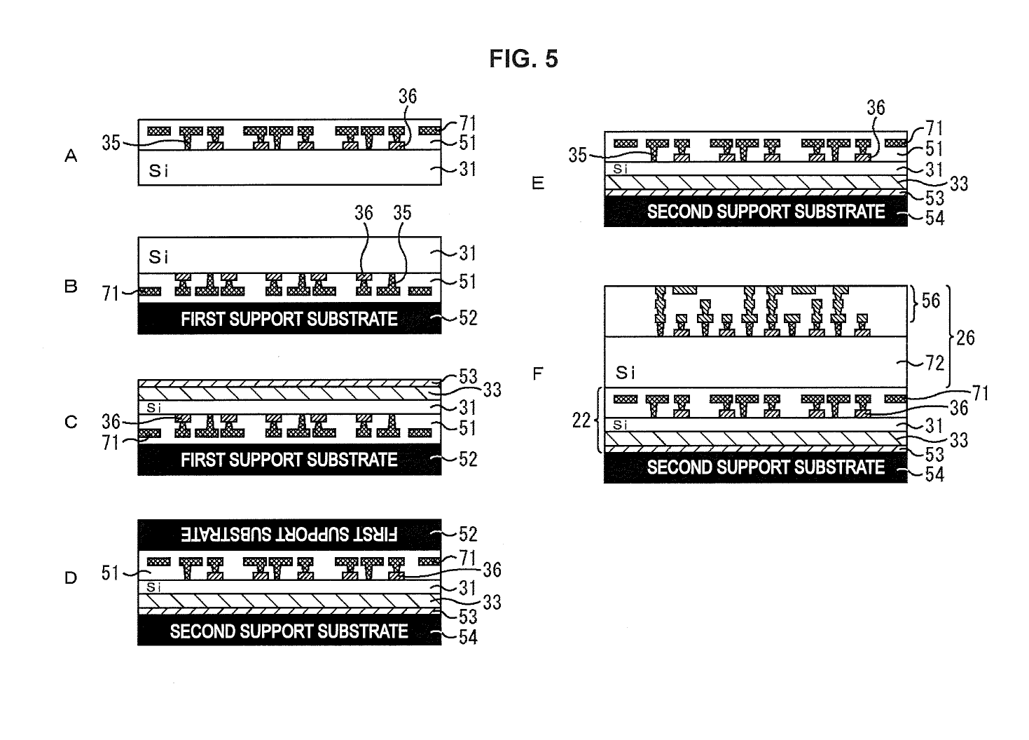

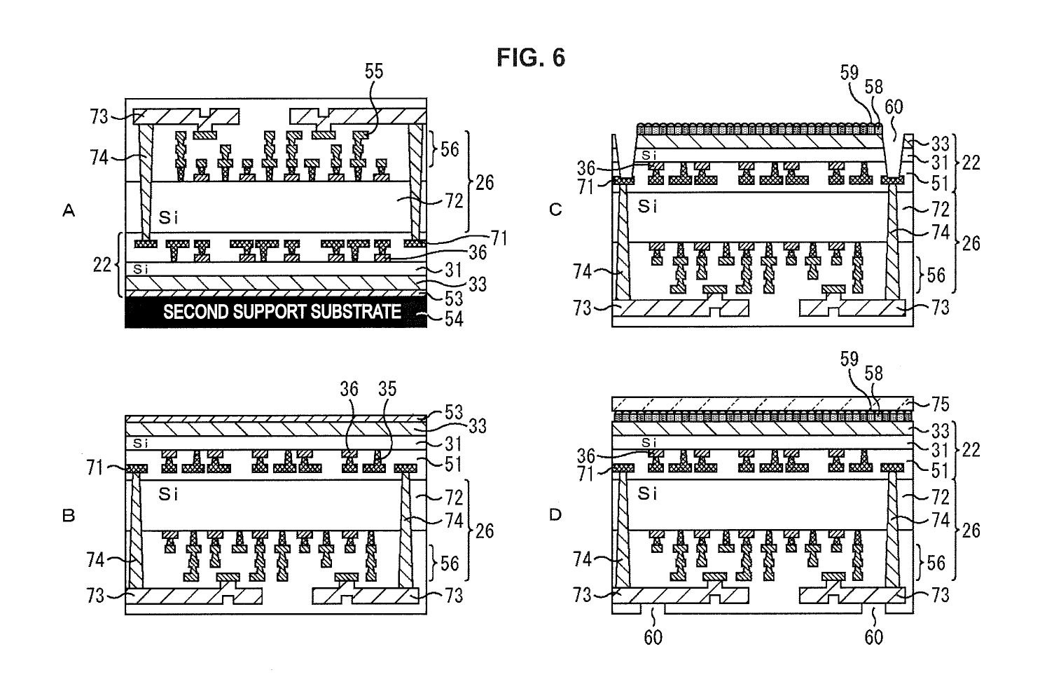

Next, a second manufacturing method of the solid-state imaging device 1 will be described with reference to FIGS. 5A to 5F and FIGS. 6A to 6D. The second to sixth manufacturing methods described below are manufacturing methods of the solid-state imaging device 1 with a configuration in which the pixel region 23 and the control circuit 24 are laminated in the vertical direction (longitudinal direction) as shown in FIGS. 2B and 2C.

In the second manufacturing method, the pixel substrate 22 with the pixel region 23 formed and the logic substrate 26 with the logic circuit 25 formed are formed separately from each other and are joined to each other. In addition, in FIGS. 5A to 5F and FIGS. 6A to 6D, the portions corresponding to FIGS. 4A to 4G are given the same reference numerals, and description thereof will be appropriately omitted.

FIGS. 5A to 5E show processes for manufacturing the pixel substrate 22.

In a first process, as shown in FIG. 5A, semiconductor elements such as MOS transistors, plugs 35, and a wire layer 71 of the pixel region 23 are formed over the silicon substrate 31. In the same manner as the plugs 35, the wire layer 71 is formed using a wire material such as tungsten (W) which can secure reliability even in the heat higher than the temperature (400° C.) at a time of forming the photoelectric conversion layer.

Second to fourth processes of FIGS. 5B to 5D are the same as the second to fourth processes (FIGS. 4B to 4D) of the above-described first manufacturing method.

In other words, in the second process, as shown in FIG. 5B, the silicon wafer is reversed, and a first support substrate 52 is joined to the front side of the silicon substrate 31. In addition, in the third process, as shown in FIG. 5C, the silicon substrate 31 is thinned through polishing or etching, and then a photoelectric conversion layer 33 and a protection film 53 are formed thereover. The protection film 53 may be made of, for example, silicon oxide (SiO₂) or silicon nitride (SiN). In the fourth process, as shown in FIG. 5D, the silicon wafer is reversed again, and a second support substrate 54 is joined to the protection film 53 side which is the rear side of the silicon substrate 31.

Next, in a fifth process, as shown in FIG. 5E, the first support substrate 52 is peeled off from the state shown in FIG. 5D.

In addition, in a sixth process, as shown in FIG. 5F, the wire layer 71 side of the pixel substrate 22 manufactured through the above-described first to fifth processes is joined to the rear side (a silicon substrate 72 side) of the logic substrate 26 manufactured through separate processes. In the logic substrate 26, semiconductor elements, a wire layer 56, and the like included in the logic circuit 25 are formed over the silicon substrate 72.

Next, it will be described with reference to FIGS. 6A to 6D. In a seventh process, as shown in FIG. 6A, metal wires 73 and connection through holes 74 for connecting the wire layer 71 of the pixel substrate 22 to the wire layer 56 of the logic substrate 26 are formed. Thereby, the pixel substrate 22 is electrically connected to the logic substrate 26.

In addition, in an eighth process, as shown in FIG. 6B, the second support substrate 54 is peeled off, and the silicon wafer is reversed again.

Next, as shown in FIG. 6C, in a ninth process, in the same manner as in the process shown in FIG. 4G of the first manufacturing method, color filters 58, on-chip lenses 59, and PAD openings 60 are formed. The protection film 53 is removed as necessary in the same manner as in the first manufacturing method (removed in FIG. 6C).

The PAD openings 60 may be provided on the opposite side of the light incident surface on which the color filters 58 and the on-chip lenses 59 are formed, as shown in FIG. 6D. In this case, the color filters 58 and the on-chip lenses 59 may be formed, and then a glass substrate 75 may be attached onto the on-chip lenses 59. The PAD openings 60 then are formed on the opposite side of the light incident surface.

As described above, according to the second manufacturing method, the wire layer 71 and the semiconductor element are formed on the front side of the silicon substrate 31 by using a wire material which can endure the temperature at a time of forming the photoelectric conversion layer, the first support substrate 52 is joined to the front side of the silicon substrate 31, the pixel substrate 22 in which the photoelectric conversion layer 33 is formed on the rear side of the silicon substrate 31 is joined to the logic substrate 26 which is manufactured through separate processes, and the pixel substrate 22 is electrically connected to the logic substrate 26, thereby manufacturing the solid-state imaging device 1. Thereby, there is a completion of the solid-state imaging device 1 with the structure shown in FIG. 3 in which the semiconductor elements and the wire layer 56 are disposed on the front side of the silicon substrate 31, and the photoelectric conversion layer 33, the color filters 58, and the like are disposed on the rear side of the silicon substrate 31.

Also in the second manufacturing method, heating of 800° C. or more is necessary to form the semiconductor elements in the first process (FIG. 5A), but since this first process precedes the third process (FIG. 5C) in which the photoelectric conversion layer 33 is formed, the photoelectric conversion layer 33 is not formed yet, and thus there is no concern about deterioration in characteristics of the photoelectric conversion layer 33 due to the heating at high temperature of 800° C. or more.

In addition, since the photoelectric conversion layer 33 is formed in the third process (FIG. 5C) preceding the sixth process (FIG. 6F) in which the logic substrate 26 provided with the wire layer 56 is joined, the heat higher than 400° C. at the time of forming the photoelectric conversion layer 33 is not applied to the wire layer 56 of the logic substrate 26, and thus it is possible to maintain reliability of the wire layer 56.

Further, although the heat higher than 400° C. at a time of forming the photoelectric conversion layer is applied to the wire layer 71 of the pixel substrate 22, the plugs 35 and the wire layer 71 are formed using a wire material such as tungsten (W) which can secure reliability even in the heat higher than the temperature at a time of forming the photoelectric conversion layer, and thus reliability of the wires is not reduced.

Therefore, also in the second manufacturing method, it is possible to prevent deterioration in characteristics of the photoelectric conversion layer and secure reliability of the wire layer.

In addition, according to the second manufacturing method, the pixel substrate 22 and the logic substrate 26 are manufactured separately from each other and are then joined to each other, and thereby the pixel region 23 and the control circuit 24 have a laminated structure. Therefore, the chip area decreases, and thus it is possible to realize reduction in manufacturing costs and miniaturization.

[Third Manufacturing Method of Solid-State Imaging Device]

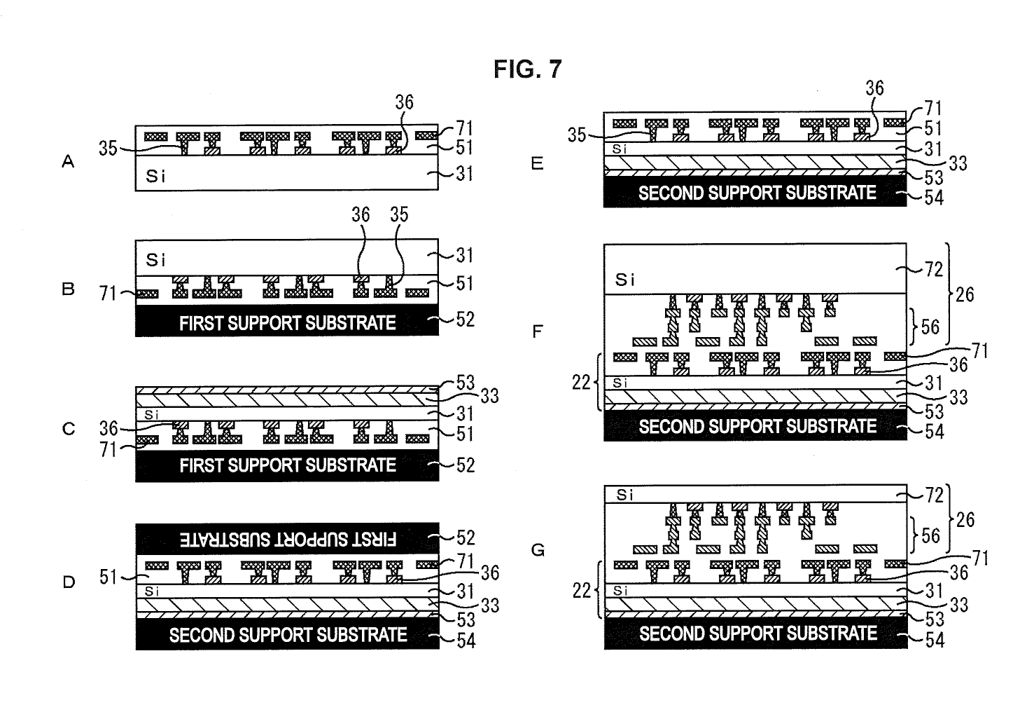

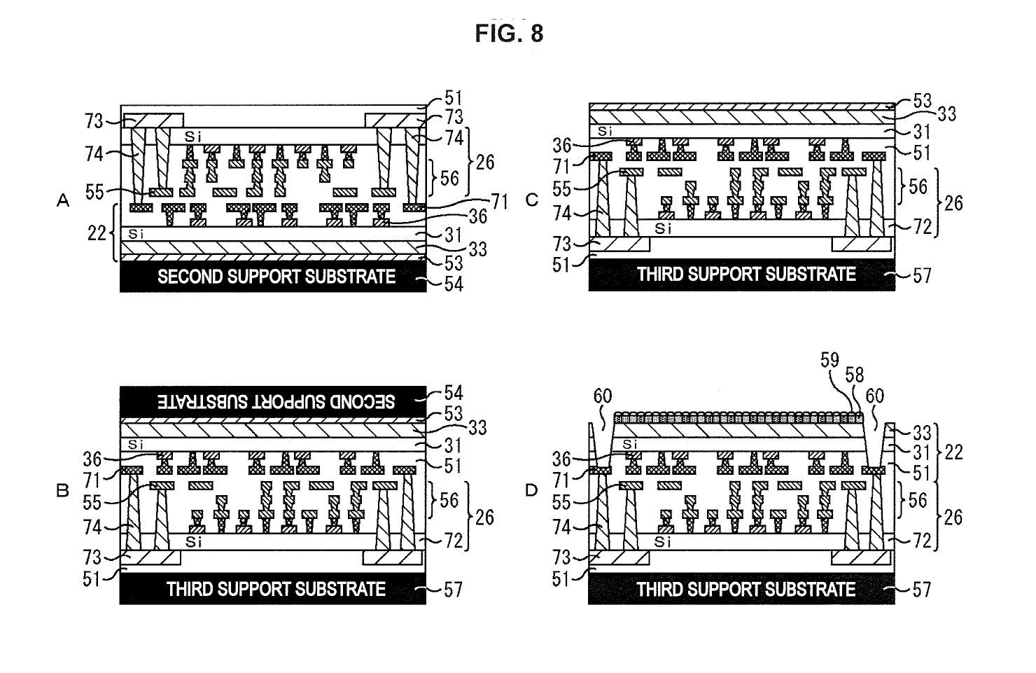

Next, a third manufacturing method of the solid-state imaging device 1 will be described with reference to FIGS. 7A to 7E and FIGS. 8A to 8D.

First to fifth processes shown in FIGS. 7A to 7E are the same as the first to fifth processes (FIGS. 5A to 5E) of the second manufacturing method, and thus description thereof will be omitted.

In a sixth process, as shown in FIG. 7F, the wire layer 71 side of the pixel substrate 22 manufactured through the above-described first to fifth processes is joined to the front side (the wire layer 56 side) of the logic substrate 26.

In other words, there is a difference in that the rear side (the silicon substrate 72 side) of the logic substrate 26 is attached to the wire layer 71 side of the pixel substrate 22 in the above-described second manufacturing method, but the front side (the wire layer 56 side) of the logic substrate 26 is attached to the wire layer 71 side of the pixel substrate 22 in the third manufacturing method.

In a seventh process, as shown in FIG. 7G, the silicon substrate 72 of the logic substrate 26 is thinned through polishing or etching.

Next, in an eighth process, as shown in FIG. 8A, metal wires 73 and connection through holes 74 for connecting the wire layer 71 of the pixel substrate 22 to the wire layer 56 of the logic substrate 26 are formed. Thereby, the pixel substrate 22 is electrically connected to the logic substrate 26. Here, a depth of the connection through hole 74 can be made to be equal to or less than, for example, 10 μm, and the depth of the connection through hole 74 can be made to be smaller than in the case of the above-described second manufacturing method by thinning the silicon substrate 72 in the seventh process.

In a ninth process, as shown in FIG. 8B, the silicon wafer is reversed, and a third support substrate 57 is joined to the rear side of the logic substrate 26.

In addition, in a tenth process, as shown in FIG. 8C, the second support substrate 54 is peeled off. In an eleventh process, as shown in FIG. 8D, in the same manner as in the process shown in FIG. 6C of the second manufacturing method, color filters 58, on-chip lenses 59, and PAD openings 60 are formed. The protection film 53 is removed as necessary in the same manner as in the second manufacturing method.

As described above, according to the third manufacturing method, the wire layer 71 and the semiconductor elements are formed on the front side of the silicon substrate 31 by using a wire material which can endure the temperature at a time of forming the photoelectric conversion layer, the first support substrate 52 is joined to the front side of the silicon substrate 31, the pixel substrate 22 in which the photoelectric conversion layer 33 is formed on the rear side of the silicon substrate 31 is joined to the logic substrate 26 which is manufactured through separate processes, and the pixel substrate 22 is electrically connected to the logic substrate 26, thereby manufacturing the solid-state imaging device 1. Thereby, there is a completion of the solid-state imaging device 1 with the structure shown in FIG. 3 in which the semiconductor elements and the wire layer 56 are disposed on the front side of the silicon substrate 31, and the photoelectric conversion layer 33, the color filters 58, and the like are disposed on the rear side of the silicon substrate 31.

Also in the third manufacturing method, heating of 800° C. or more is necessary to form the semiconductor elements in the first process (FIG. 7A), but since this process precedes the third process (FIG. 7C) in which the photoelectric conversion layer 33 is formed, the photoelectric conversion layer 33 is not formed yet, and thus there is no concern about deterioration in characteristics of the photoelectric conversion layer 33 due to the heating at high temperature of 800° C. or more.

In addition, since the photoelectric conversion layer 33 is formed in the third process (FIG. 7C) preceding the sixth process (FIG. 7F) in which the logic substrate 26 provided with the wire layer 56 is joined, the heat higher than 400° C. at the time of forming the photoelectric conversion layer 33 is not applied to the wire layer 56, and thus it is possible to maintain reliability of the wire layer 56.

Therefore, also in the third manufacturing method, it is possible to prevent deterioration in characteristics of the photoelectric conversion layer and secure reliability of the wire layer. In addition, since the pixel region 23 and the control circuit 24 have a laminated structure, the chip area decreases, and thus it is possible to realize reduction in manufacturing costs and miniaturization.

Further, according to the third manufacturing method, the depth of the connection through hole 74 can be made to be smaller than in the case of the second manufacturing method.

[Fourth Manufacturing Method of Solid-State Imaging Device]

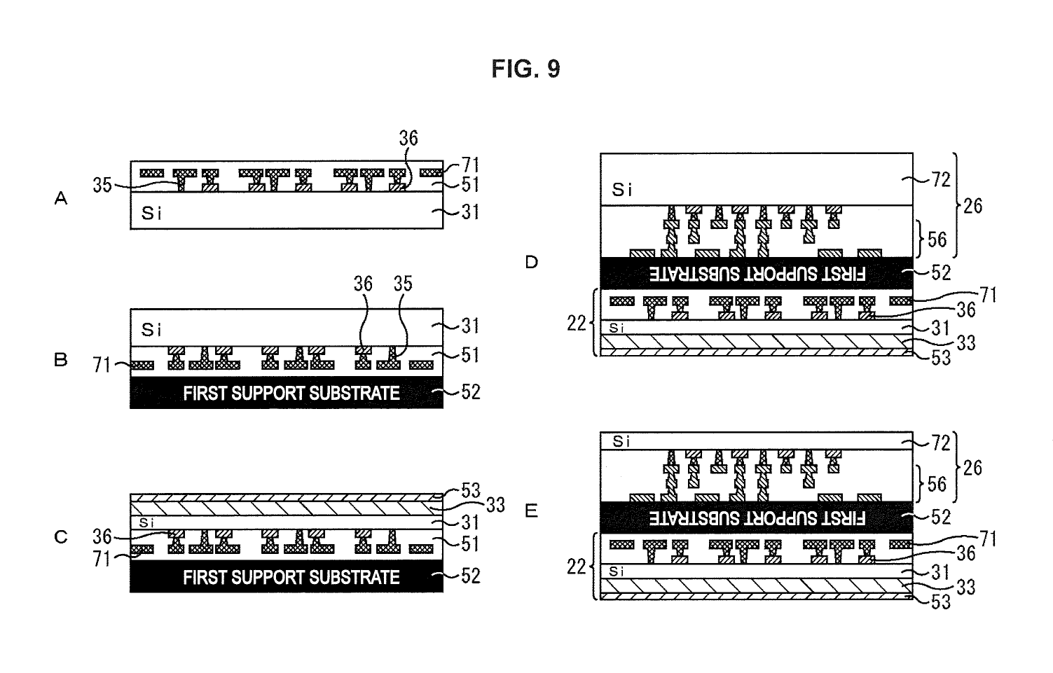

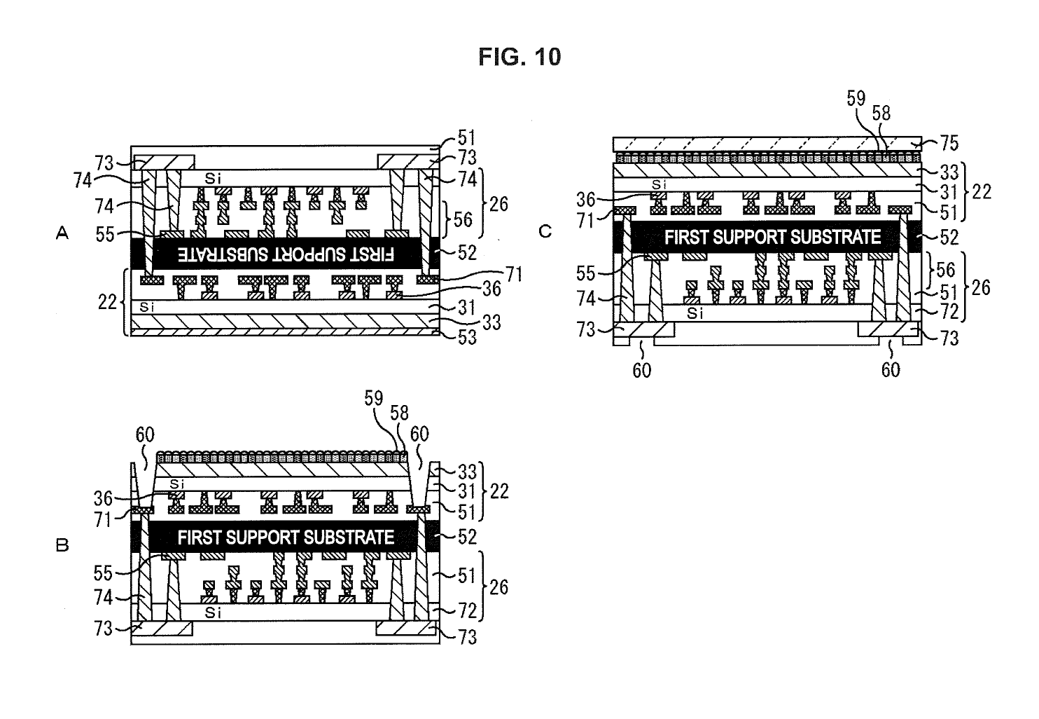

Next, a fourth manufacturing method of the solid-state imaging device 1 will be described with reference to FIGS. 9A to 9E and FIGS. 10A to 10C.

First to third processes shown in FIGS. 9A to 9C are the same as the first to third processes (FIGS. 7A to 7C) of the third manufacturing method, and thus description thereof will be omitted.

In a fourth process, as shown in FIG. 9D, the silicon wafer is reversed, and the front side (the wire layer 56 side) of the logic substrate 26 which is manufactured through separate processes is joined to the rear side of the first support substrate 52.

In a fifth process, as shown in FIG. 9E, the silicon substrate 72 of the logic substrate 26 is thinned through polishing or etching.

Next, referring to FIGS. 10A to 10C, in a sixth process, as shown in FIG. 10A, metal wires 73 and connection through holes 74 for connecting the wire layer 71 of the pixel substrate 22 to the wire layer 56 of the logic substrate 26 are formed. Thereby, the pixel substrate 22 is electrically connected to the logic substrate 26. Here, since the first support substrate 52 is interposed between the wire layer 71 of the pixel substrate 22 and the wire layer 56 of the logic substrate 26, the connection through hole 74 penetrates through the first support substrate 52.

In a seventh process, as shown in FIG. 10B, the silicon wafer is reversed again, and, in the same manner as in the ninth process (FIG. 6C) of the second manufacturing method, color filters 58, on-chip lenses 59, and PAD openings 60 are formed. The protection film 53 is removed as necessary in the same manner as in the second manufacturing method.

Alternatively, in the seventh process, the PAD openings 60 are formed on the opposite side of the light incident surface as shown in FIG. 10C. In this case, a glass substrate 75 is disposed on the on-chip lenses 59 in the same manner as in the above-described second manufacturing method.

As described above, according to the fourth manufacturing method, the wire layer 71 and the semiconductor elements are formed on the front side of the silicon substrate 31 by using a wire material which can endure the temperature at a time of forming the photoelectric conversion layer, the first support substrate 52 is joined to the front side of the silicon substrate 31, the pixel substrate 22 in which the photoelectric conversion layer 33 is formed on the rear side of the silicon substrate 31 is joined to the logic substrate 26 which is manufactured through separate processes, and the pixel substrate 22 is electrically connected to the logic substrate 26, thereby manufacturing the solid-state imaging device 1. Thereby, there is a completion of the solid-state imaging device 1 with the structure shown in FIG. 3 in which the semiconductor elements and the wire layer 56 are disposed on the front side of the silicon substrate 31, and the photoelectric conversion layer 33, the color filters 58, and the like are disposed on the rear side of the silicon substrate 31.

Also in the fourth manufacturing method, heating of 800° C. or more is necessary to form the semiconductor elements in the first process (FIG. 9A), but since this process precedes the third process (FIG. 9C) in which the photoelectric conversion layer 33 is formed, the photoelectric conversion layer 33 is not formed yet, and thus there is no concern about deterioration in characteristics of the photoelectric conversion layer 33 due to the heating at high temperature of 800° C. or more.

In addition, since the photoelectric conversion layer 33 is formed in the third process (FIG. 9C) preceding the fourth process (FIG. 9D) in which the logic substrate 26 provided with the wire layer 56 is joined, the heat higher than 400° C. at the time of forming the photoelectric conversion layer 33 is not applied to the wire layer 56, and thus it is possible to maintain reliability of the wire layer 56.

Therefore, also in the fourth manufacturing method, it is possible to prevent deterioration in characteristics of the photoelectric conversion layer and secure reliability of the wire layer.

[Fifth Manufacturing Method of Solid-State Imaging Device]

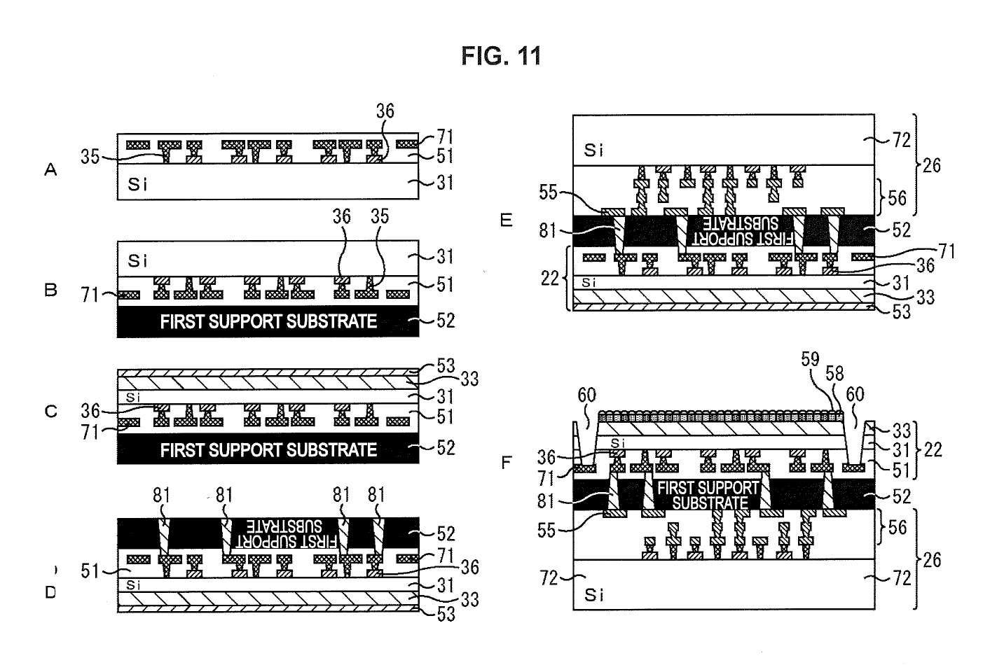

Next, a fifth manufacturing method of the solid-state imaging device 1 will be described with reference to FIGS. 11A to 11F.

First to third processes shown in FIGS. 11A to 11C are the same as the first to third processes (FIGS. 10A to 10C) of the fourth manufacturing method, and thus description thereof will be omitted. Through the first to third processes, the wire layer 71 of the pixel substrate 22, the silicon substrate 31, the photoelectric conversion layer 33, and the protection film 53 are formed over the first support substrate 52.

In a fourth process, as shown in FIG. 11D, the silicon wafer is reversed, and connection through holes 81 are formed which penetrate through the first support substrate 52 and are connected to the wire layer 71 of the pixel substrate 22.

In a fifth process, as shown in FIG. 11E, in the same manner as in the fourth process (FIG. 9D) of the fourth manufacturing method, the front side (the wire layer 56 side) of the logic substrate 26 which is manufactured through separate processes is joined to the rear side of the first support substrate 52. Thereby, the wire layer 71 of the pixel substrate 22 is connected to the wire layer 56 of the logic substrate 26 via the connection through holes 81.

In addition, in a sixth process, as shown in FIG. 11F, the silicon wafer is reversed, and, in the same manner as in the seventh process (FIG. 10B) of the fourth manufacturing method, color filters 58, on-chip lenses 59, and PAD openings 60 are formed.

The PAD openings 60 may be formed on the opposite side of the light incident surface in the same manner as in FIG. 10C of the fourth manufacturing method.

As described above, according to the fifth manufacturing method, the wire layer 71 and the semiconductor elements are formed on the front side of the silicon substrate 31 by using a wire material which can endure the temperature at a time of forming the photoelectric conversion layer, the first support substrate 52 is joined to the front side of the silicon substrate 31, the pixel substrate 22 in which the photoelectric conversion layer 33 is formed on the rear side of the silicon substrate 31 is joined to the logic substrate 26 which is manufactured through separate processes, and the pixel substrate 22 is electrically connected to the logic substrate 26, thereby manufacturing the solid-state imaging device 1. Thereby, there is a completion of the solid-state imaging device 1 with the structure shown in FIG. 3 in which the semiconductor elements and the wire layer 56 are disposed on the front side of the silicon substrate 31, and the photoelectric conversion layer 33, the color filters 58, and the like are disposed on the rear side of the silicon substrate 31.

Also in the fifth manufacturing method, heating of 800° C. or more is necessary to form the semiconductor elements in the first process (FIG. 11A), but since this process precedes the third process (FIG. 11C) in which the photoelectric conversion layer 33 is formed, the photoelectric conversion layer 33 is not formed yet, and thus there is no concern about deterioration in characteristics of the photoelectric conversion layer 33 due to the heating at high temperature of 800° C. or more.

In addition, since the photoelectric conversion layer 33 is formed in the third process (FIG. 11C) preceding the fifth process (FIG. 11E) in which the logic substrate 26 provided with the wire layer 56 is joined, the heat higher than 400° C. at the time of forming the photoelectric conversion layer 33 is not applied to the wire layer 56, and thus it is possible to maintain reliability of the wire layer 56.

Therefore, also in the fifth manufacturing method, it is possible to prevent deterioration in characteristics of the photoelectric conversion layer and secure reliability of the wire layer.

In addition, in a structure of the solid-state imaging device 1 which is manufactured using the fifth manufacturing method, a support substrate having an anisotropic conductor characteristic may be employed as the first support substrate 52, and, in this case, the connection through holes 81 are not necessary.

[Sixth Manufacturing Method of Solid-State Imaging Device]

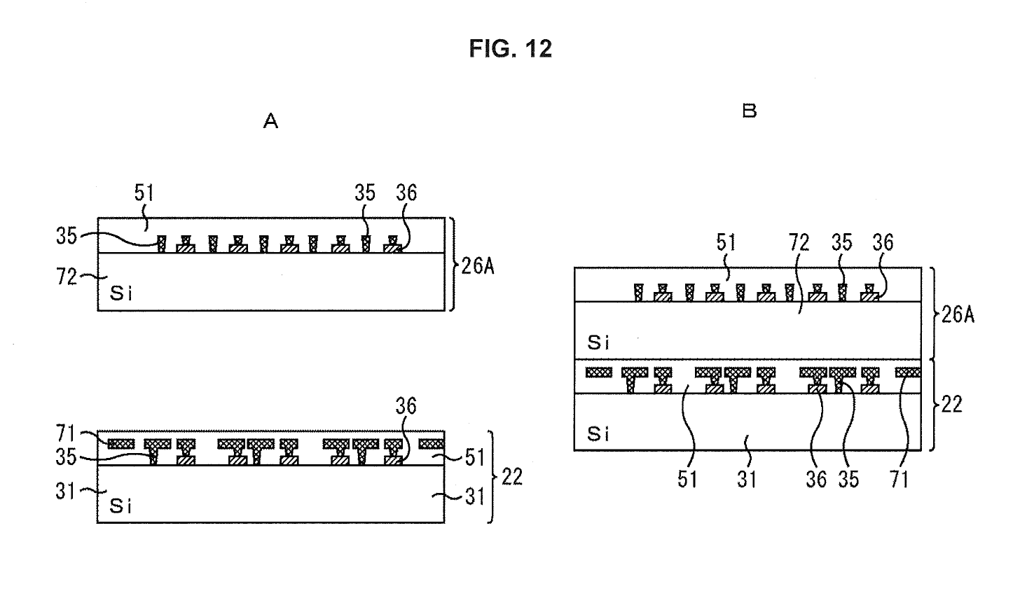

Next, a sixth manufacturing method of the solid-state imaging device 1 will be described with reference to FIG. 12A to FIG. 14B.

In a first process, as shown in FIG. 12A, a pixel substrate 22 and a logic substrate 26A are manufactured in different processes. Here, the logic substrate 26A is different from the logic substrate 26 which is joined in the above-described second to fifth manufacturing methods in that a wire layer 71 is not formed yet. In addition, plugs 35 of the logic substrate 26A are formed using a wire material such as tungsten (W) which can secure reliability even in the heat higher than 400° C. at the time of forming the photoelectric conversion layer 33 in the same manner as the plugs 35 of the pixel substrate 22.

Further, as shown in FIG. 12B, in a second process, the wire layer 71 side of the pixel substrate 22 and the rear side (the silicon substrate 72 side) of the logic substrate 26A which are manufactured through the separate processes are joined to each other.

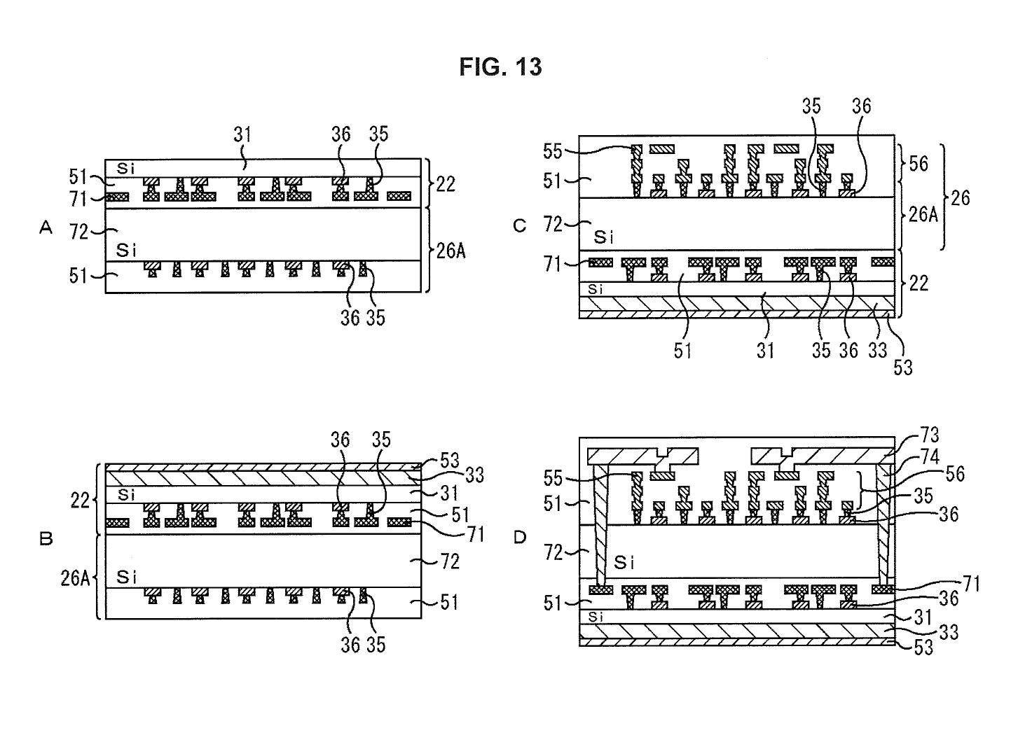

Referring to FIGS. 13A to 13D, in a third process, as shown in FIG. 13A, the silicon wafer is reversed, and the silicon substrate 31 on the upper side of the pixel substrate 22 is thinned through polishing or etching.

In addition, in a fourth process, as shown in FIG. 13B, a photoelectric conversion layer 33 and a protection film 53 are formed over the thinned silicon substrate 31.

Next, in a fifth process, as shown in FIG. 13C, the silicon wafer is reversed again, and a wire layer 56 including multi-layer wires 55 is formed on the front side of the logic substrate 26A by using Al or Cu as a wire material. Thereby, the pixel substrate 22 and the logic substrate 26 are in a laminated state as in FIG. 5F of the second manufacturing method.

In a sixth process shown in FIG. 13D, in the same manner as in the seventh process (FIG. 6A) of the second manufacturing method, metal wires 73 and connection through holes 74 for connecting the wire layer 71 of the pixel substrate 22 to the wire layer 56 of the logic substrate 26 are formed. Thereby, the pixel substrate 22 is electrically connected to the logic substrate 26.

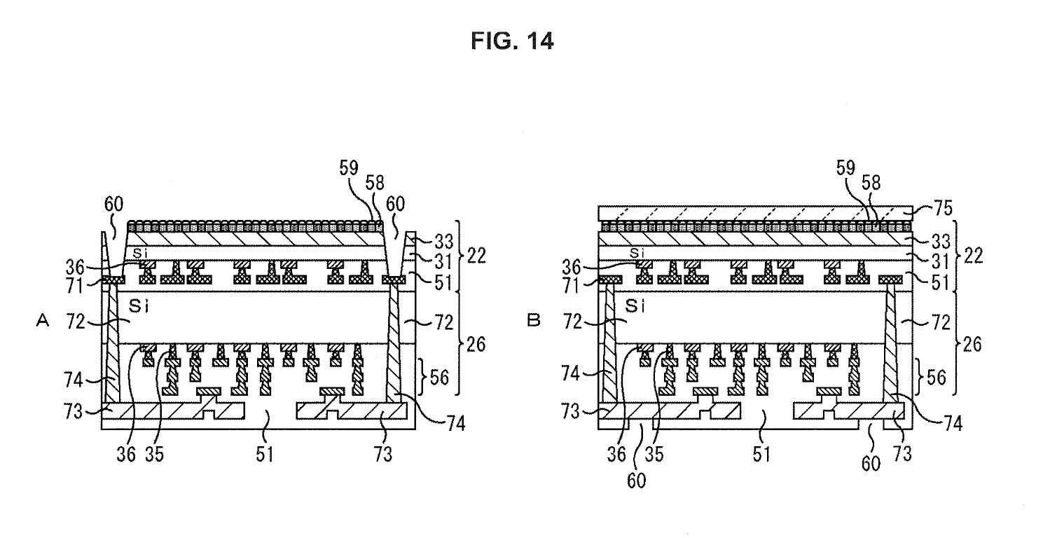

Referring to FIGS. 14A and 14B, in a seventh process, as shown in FIG. 14A, the silicon wafer is reversed again, and, in the same manner as in the ninth process (FIG. 6C) of the second manufacturing method, color filters 58, on-chip lenses 59, and PAD openings 60 are formed.

Alternatively, as shown in FIG. 14B, a glass substrate 75 may be attached onto the on-chip lenses 59, and the PAD openings 60 may be formed on the opposite side of the light incident surface.

As described above, according to the sixth manufacturing method, the wire layer 71 side of the pixel substrate 22 on which the wire layer 71 and the semiconductor element are formed by using a wire material which can endure the temperature at a time of forming the photoelectric conversion layer is joined to the rear side of the logic substrate 26A on which the semiconductor elements are formed, the photoelectric conversion layer 33 is formed on the rear side of the pixel substrate 22, and then the wire layer 56 is formed in the logic substrate 26A, thereby manufacturing the solid-state imaging device 1. Thereby, there is a completion of the solid-state imaging device 1 with the structure shown in FIG. 3 in which the semiconductor elements and the wire layer 56 are disposed on the front side of the silicon substrate 31, and the photoelectric conversion layer 33, the color filters 58, and the like are disposed on the rear side of the silicon substrate 31.

Also in the sixth manufacturing method, heating of 800° C. or more is necessary to form the semiconductor elements in the first process (FIG. 12A), but since this process precedes the fourth process (FIG. 13B) in which the photoelectric conversion layer 33 is formed, the photoelectric conversion layer 33 is not formed yet, and thus there is no concern about deterioration in characteristics of the photoelectric conversion layer 33 due to the heating at high temperature of 800° C. or more.

In addition, since the photoelectric conversion layer 33 is formed in the fourth process (FIG. 13B) preceding the fifth process (FIG. 13C) in which the wire layer 56 is formed, the heat higher than 400° C. at the time of forming the photoelectric conversion layer 33 is not applied to the wire layer 56, and thus it is possible to maintain reliability of the wire layer 56.

Therefore, also in the sixth manufacturing method, it is possible to prevent deterioration in characteristics of the photoelectric conversion layer and secure reliability of the wire layer.

In addition, in the sixth manufacturing method, the number of times being joined between layers can be reduced to one time, and thus it is possible to further reduce manufacturing costs than in the above-described first to fifth manufacturing methods.

Further, although, in the above-described example, the plugs 35 have already been formed in the logic substrate 26A (FIG. 12A) before being joined to the pixel substrate 22, the plugs 35 may be formed in the logic substrate 26A before the wire layer 56 is formed in the fifth process (FIG. 13C).

[Application Example to Electronic Apparatus]

The above-described solid-state imaging device 1 is applicable to, for example, an imaging apparatus such as a digital still camera or a digital video camera, a mobile phone having an imaging function, or a variety of electronic apparatuses such as other apparatuses having an imaging function.

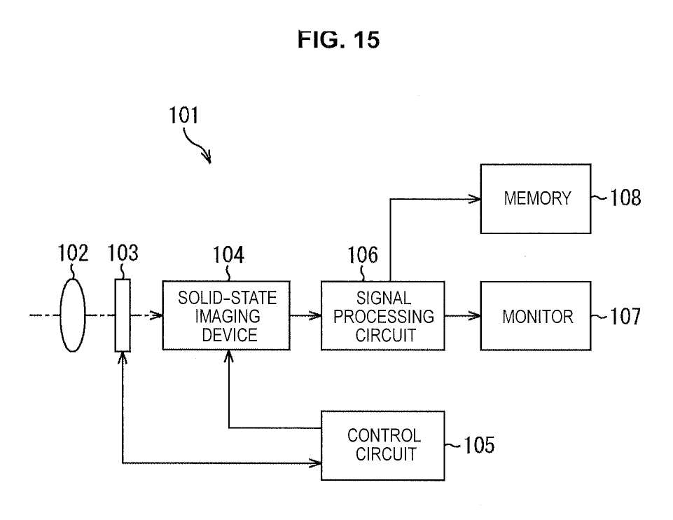

FIG. 15 is a block diagram illustrating a configuration example of the imaging apparatus which is an electronic apparatus to which an embodiment of the present technology is applied.

An imaging apparatus 101 shown in FIG. 15 includes an optical system 102, a shutter device 103, a solid-state imaging device 104, a control circuit 105, a signal processing circuit 106, a monitor 107, and a memory 108. The imaging apparatus 101 can capture still images and moving images.

The optical system 102 includes one or a plurality of lenses, and guides light (incident light) from a subject to the solid-state imaging device 104 so as to be imaged on a light receiving surface of the solid-state imaging device 104.

The shutter device 103 is disposed between the optical system 102 and the solid-state imaging device 104, and controls a light irradiation period and a light blocking period with respect to the solid-state imaging device 104 under the control of the control circuit 105.

The solid-state imaging device 104 is constituted by the above-described solid-state imaging device 1. The solid-state imaging device 104 accumulates signal charge during a certain period according to light imaged on the light receiving surface via the optical system 102 and the shutter device 103. The signal charge accumulated in the solid-state imaging device 104 is transferred in response to a driving signal (a timing signal) supplied from the control circuit 105. The solid-state imaging device 104 may be formed singly as one chip or may be formed as a part of a camera module which is packaged along with components including the optical system 102, the signal processing circuit 106 and the like.

The control circuit 105 outputs driving signals for controlling a transfer operation of the solid-state imaging device 104 and a shutter operation of the shutter device 103 to drive the solid-state imaging device 104 and the shutter device 103.

The signal processing circuit 106 performs various signal processes on the signal charge output from the solid-state imaging device 104. An image (image data) obtained by the signal processing circuit 106 performing the signal processes is supplied to the monitor 107 so as to be displayed, or is supplied to the memory 108 so as to be stored (recorded).

It should be understood by those skilled in the art that various modifications, combinations, sub-combinations and alterations may occur depending on design requirements and other factors insofar as they are within the scope of the appended claims or the equivalents thereof

Additionally, the present technology may also be configured as below.
(1)
A solid-state imaging device including:

a pixel substrate in which a wire layer and a semiconductor element are formed using a wire material which can endure temperature at a time of forming a photoelectric conversion layer; and

a logic substrate in which a semiconductor element is formed,

wherein the wire layer side of the pixel substrate is joined to a rear side of the logic substrate, and, after the photoelectric conversion layer is formed on a rear side of the pixel substrate, a wire layer is formed in the logic substrate such that the wire layers are disposed on a front side of the pixel substrate and the photoelectric conversion layer is disposed on the rear side of the pixel substrate.
(2)
The solid-state imaging device according to (1), wherein a semiconductor substrate of the pixel substrate is thinned, and then the photoelectric conversion layer is formed on the rear side of the pixel substrate.
(3)
The solid-state imaging device according to (1) or (2), wherein the photoelectric conversion layer is formed through epitaxial growth.
(4)
The solid-state imaging device according to any one of (1) to (3), wherein the photoelectric conversion layer is made of a chalcopyrite-based compound semiconductor.
(5)
The solid-state imaging device according to any one of (1) to (4), wherein a PAD opening is formed on an opposite side to a light incident surface.
(6)
A solid-state imaging device including:

a pixel substrate in which a wire layer and a semiconductor element are formed on a front side of a semiconductor substrate by using a wire material which can endure temperature at a time of forming a photoelectric conversion layer, a support substrate is then joined to the front side of the semiconductor substrate, and the photoelectric conversion layer is formed on a rear side of the semiconductor substrate; and

a logic substrate manufactured separately from the pixel substrate,

wherein the pixel substrate is joined to the logic substrate such that the pixel substrate is electrically connected to the logic substrate, and the wire layer is disposed on a front side of the pixel substrate and the photoelectric conversion layer is disposed on a rear side of the pixel substrate.
(7)
The solid-state imaging device according to (6), wherein a wire side of the pixel substrate is joined to a semiconductor substrate side of the logic substrate.
(8)
The solid-state imaging device according to (6), wherein a wire side of the pixel substrate is joined to a wire side of the logic substrate.
(9)
The solid-state imaging device according to (8), wherein the wire side of the pixel substrate is joined to the wire side of the logic substrate, and then a semiconductor substrate of the logic substrate is thinned.
(10)
The solid-state imaging device according to (6), wherein the support substrate is joined to a wire side of the logic substrate.
(11)
The solid-state imaging device according to (10), wherein a connection through hole which penetrates through the support substrate is formed before the support substrate is joined to the wire side of the logic substrate.
(12)
The solid-state imaging device according to (10), wherein an anisotropic conductor is used as the support substrate.
(13)
A solid-state imaging device including:

a pixel substrate that is formed by, after a semiconductor element is formed on a front side of a semiconductor substrate, joining a support substrate to the front side of the semiconductor substrate, and, after a photoelectric conversion layer is formed on a rear side of the semiconductor substrate, forming a wire layer,

wherein the wire layer is disposed on a front side of the pixel substrate and the photoelectric conversion layer is disposed on a rear side of the pixel substrate.
(14)
An electronic apparatus including the solid-state imaging device according to any one of (1), (6), and (13).

The present disclosure contains subject matter related to that disclosed in Japanese Priority Patent Application JP 2012-149099 filed in the Japan Patent Office on Jul. 3, 2012, the entire content of which is hereby incorporated by reference.

What is claimed is:

1. A solid-state imaging device comprising:
a pixel substrate in which a wire layer and a semiconductor element are formed using a wire material which can endure temperature at a time of forming a photoelectric conversion layer; and
a logic substrate in which a semiconductor element is formed,
wherein the wire layer side of the pixel substrate is joined to a rear side of the logic substrate, and, after the photoelectric conversion layer is formed on a rear side of the pixel substrate, a wire layer is formed in the logic substrate such that the wire layers are disposed on a front side of the pixel substrate and the photoelectric conversion layer is disposed on the rear side of the pixel substrate.

2. The solid-state imaging device according to claim 1, wherein a semiconductor substrate of the pixel substrate is thinned, and then the photoelectric conversion layer is formed on the rear side of the pixel substrate.

3. The solid-state imaging device according to claim 1, wherein the photoelectric conversion layer is formed through epitaxial growth.

4. The solid-state imaging device according to claim 1, wherein the photoelectric conversion layer is made of a chalcopyrite-based compound semiconductor.

5. The solid-state imaging device according to claim 1, wherein a PAD opening is formed on an opposite side to a light incident surface.

6. A solid-state imaging device comprising:
a pixel substrate in which a wire layer and a semiconductor element are formed on a front side of a semiconductor substrate by using a wire material which can endure temperature at a time of forming a photoelectric conversion layer, a support substrate is then joined to the front side of the semiconductor substrate, and the photoelectric conversion layer is formed on a rear side of the semiconductor substrate; and
a logic substrate manufactured separately from the pixel substrate,
wherein the pixel substrate is joined to the logic substrate such that the pixel substrate is electrically connected to the logic substrate, and the wire layer is disposed on a front side of the pixel substrate and the photoelectric conversion layer is disposed on a rear side of the pixel substrate.

7. The solid-state imaging device according to claim 6, wherein a wire side of the pixel substrate is joined to a semiconductor substrate side of the logic substrate.

8. The solid-state imaging device according to claim 6, wherein a wire side of the pixel substrate is joined to a wire side of the logic substrate.

9. The solid-state imaging device according to claim 8, wherein the wire side of the pixel substrate is joined to the wire side of the logic substrate, and then a semiconductor substrate of the logic substrate is thinned.

10. The solid-state imaging device according to claim 6, wherein the support substrate is joined to a wire side of the logic substrate.

11. The solid-state imaging device according to claim 10, wherein a connection through hole which penetrates through the support substrate is formed before the support substrate is joined to the wire side of the logic substrate.

12. The solid-state imaging device according to claim 10, wherein an anisotropic conductor is used as the support substrate.

13. A solid-state imaging device comprising:
a pixel substrate that is formed by, after a semiconductor element is formed on a front side of a semiconductor substrate, joining a support substrate to the front side of the semiconductor substrate, and, after a photoelectric conversion layer is formed on a rear side of the semiconductor substrate, forming a wire layer,
wherein the wire layer is disposed on a front side of the pixel substrate and the photoelectric conversion layer is disposed on a rear side of the pixel substrate.

14. An electronic apparatus comprising the solid-state imaging device according to claim 1.
